(19) United States
(12) Patent Application Publication
(10) Pub. No.: US 2006/0043586 A1
(43) Pub. Date: Mar. 2, 2006

(54) Board level solder joint support for BGA packages under heatsink compression

(75) Inventors: Tz-Cheng Chiu, Plano, TX (US); Shih-Fang Chuang, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/924,500

(22) Filed: Aug. 24, 2004

(51) Int. Cl. H01L 23/48

(52) U.S. Cl. 257/738

(57) ABSTRACT

A system comprising a ball grid array (“BGA”) substrate adapted to electrically couple to an application board using a plurality of solder balls, and a film adapted to abut the application board and the BGA substrate, the film comprising a plurality of perforations, the solder balls adapted to couple to the application board through the perforations.

### BACKGROUND

A ball grid array (“BGA”) package is a type of chip package wherein solder balls are used to electrically connect the BGA package to a structure external to the package, such as a printed circuit board (“PCB”). The solder balls conduct electrical signals between a chip inside the package and the external structure. A BGA package is electrically coupled to a PCB using the solder balls during a solder reflow process. During a solder reflow process, the solder balls are heated such that the solder balls melt (i.e., “reflow”) and form electrical connections (i.e., metallic bonding) with the PCB.

Many BGA packages have heatsinks coupled to a surface of the BGA package opposite the solder balls. FIG. 1 shows one such BGA package 100 abutting a heatsink 102. The BGA package 100 comprises a chip 10 abutting a substrate 20. The BGA package 100 is electrically coupled to a PCB 104 by way of multiple solder balls 106 that are coupled to the substrate 20 at solder joints 108. The heatsink 102 is assembled abutting the BGA package 100 after the BGA package 100 is reflowed to the PCB 104. The heatsink 102 is assembled abutting the BGA package 100 either through adhesive attach, spring clipping, or screw and backing plate assembly. The weight of the heatsink 102 may add stress to the solder balls 106 and the solder joints 108, thus damaging the solder joints 108. In cases where the heatsink 102 is screwed to a backing plate 50 using screws 52 as shown in FIG. 1, a compressive force caused by the heatsink 102 and the screws 52 also may cause the solder joints 108 to be damaged. Damaged solder joints 108 may render the BGA package 100 useless.

The stress resulting from the weight and compressive force from the heatsink 102 also may cause the solder balls 106 to be compressed in between the BGA package 100 and the PCB 104 to a degree greater than in a typical solder reflow process. This compression causes each solder ball 106 to creep and progressively expand toward adjacent solder balls 106, as shown in FIGS. 2a-2c. Specifically, FIG. 2a shows the solder balls 106 prior to creeping. FIG. 2b shows the solder balls 106 expanding toward each other due to compression between the substrate 20 and the PCB 104 (i.e., caused by the weight and/or compression of the heatsink 102/screws 52/backing plate 50 assembly). As shown in FIG. 2c, a sufficient amount of creeping under compression may cause at least some of the solder balls 106 to come into electrical contact with each other, resulting in multiple short circuits. These short circuits may render the BGA package 100 and/or the PCB 104 useless.

One possible solution to such a problem is to apply a polymer underfill between the substrate 20 and the PCB 104. However, applying an underfill prevents the package 100 from being removed from the PCB 104. For example, if the package 100 does not function properly, the package 100 cannot be removed from the PCB 104 and replaced with a properly functioning package. Leaving an improperly-functioning package 100 on the PCB 104 substantially increases cost, particularly in applications such as servers and telecommunications.

### BRIEF SUMMARY

The problems noted above are solved in large part by a solder joint support film for BGA packages under heatsink compression. One exemplary embodiment may be a system comprising a ball grid array (“BGA”) substrate adapted to electrically couple to an application board using a plurality of solder balls, and a film adapted to abut the application board and the BGA substrate, said film comprising a plurality of perforations, the solder balls adapted to couple to the application board through said perforations.

### BRIEF DESCRIPTION OF THE DRAWINGS

For a detailed description of exemplary embodiments of the invention, reference will now be made to the accompanying drawings in which:

FIG. 1 shows a BGA package electrically coupled to a PCB and a heatsink assembled abutting the package;

FIGS. 2a-2c show the progressive compression creeping of solder balls as the substrate is pushed closer to the PCB due to the compressive load from the heatsink;

FIG. 3 shows a thin film having multiple perforations, in accordance with a preferred embodiment of the invention;

FIG. 4a shows the thin film abutting the substrate, in accordance with embodiments of the invention;

FIG. 4b shows a PCB abutting the substrate and thin film configuration of FIG. 4a, in accordance with embodiments of the invention;

FIG. 4c shows the thin film between the substrate and the PCB, in accordance with embodiments of the invention; and

FIG. 5 shows a flow chart in accordance with embodiments of the invention.

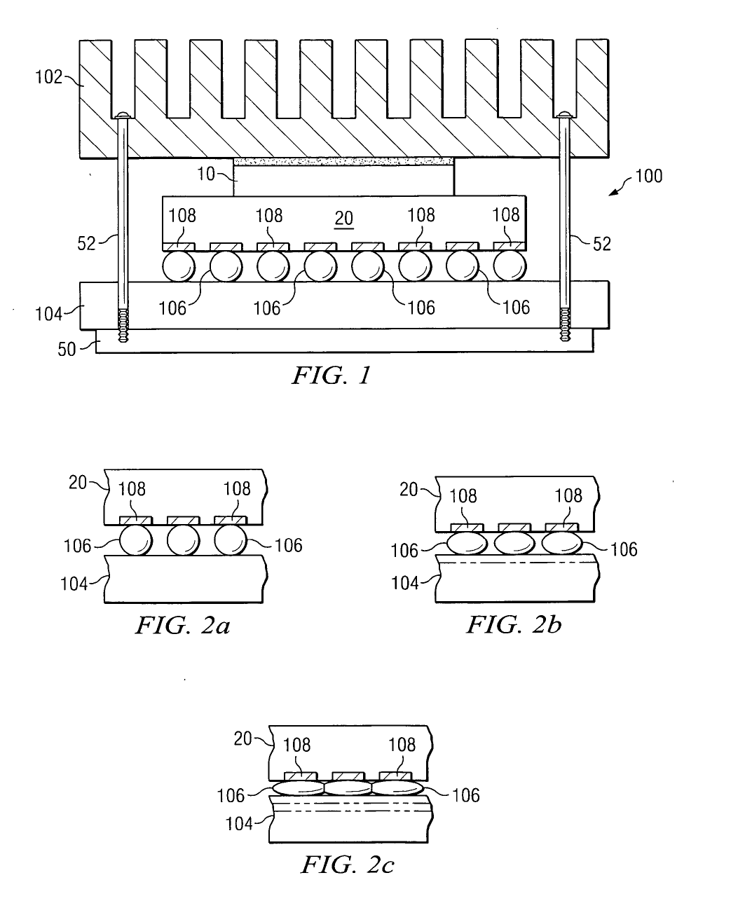

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Presented herein is a device that supports BGA package solder joints and prevents solder ball short circuiting. Specifically, a perforated thin film is deposited between a BGA package and a PCB to provide mechanical support to the solder joints and the BGA package during a solder reflow process. The perforated thin film also prevents the solder balls from coming into electrical contact with each other due to stress applied by a heatsink abutting the BGA package.

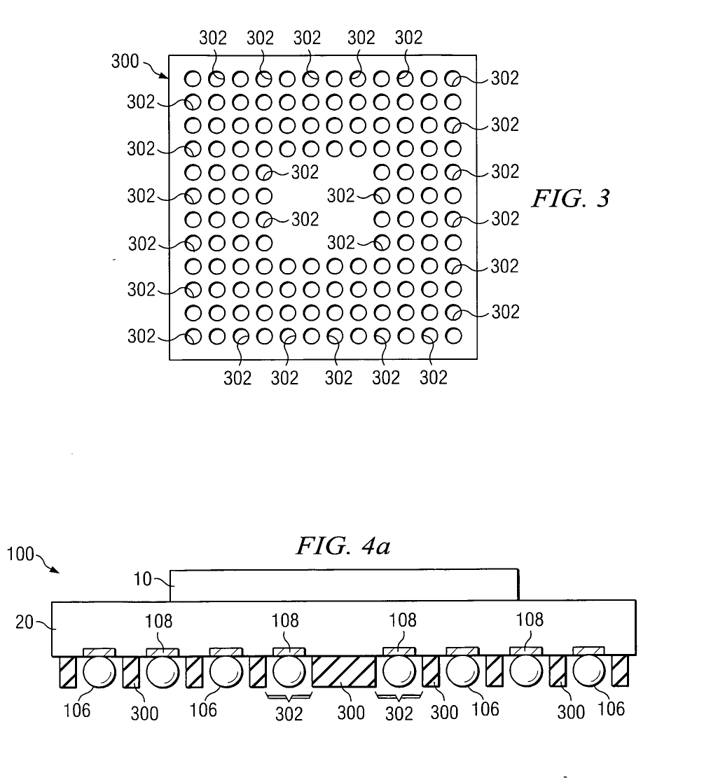

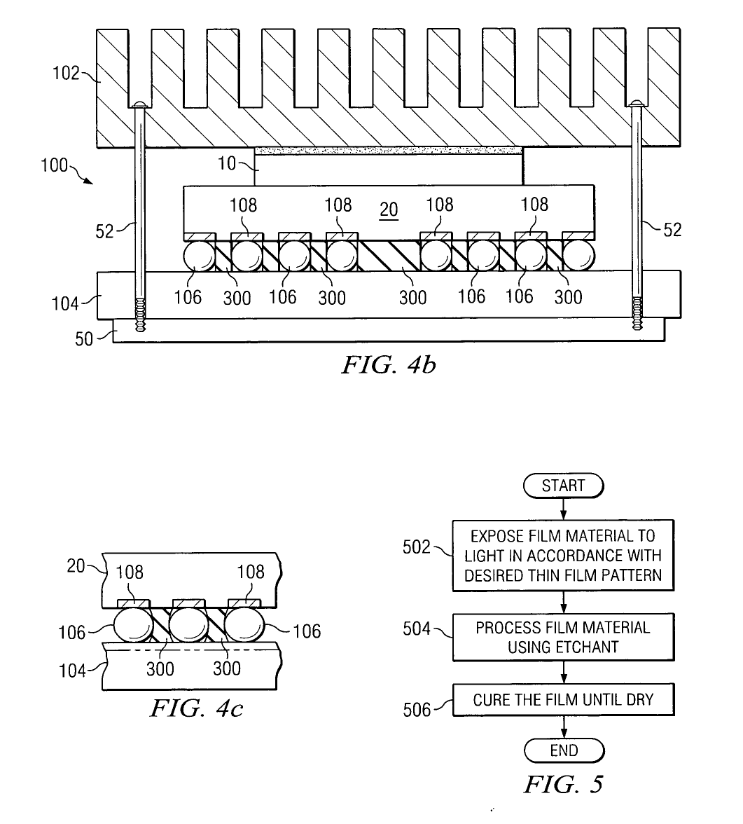

FIG. 3 shows a top view of a thin film 300 comprising a plurality of perforations 302. The perforations 302 preferably are produced to align with a BGA package solder ball pattern with which the thin film 300 is to be used, although any arrangement of perforations 302 may be used. Likewise, the thin film 300 may have dimensions of any suitable size. In particular, the thin film 300 preferably has a thickness substantially similar to that of the diameter (e.g., height) of the solder balls 106. The thin film 300 may have a thickness greater than approximately 25.0 micrometers, although the scope of disclosure is not limited to these dimensions. FIG. 4a shows a cross sectional side view of the chip 10 abutting the BGA substrate 20. The BGA substrate 20 is electrically coupled to the multiple solder balls 106. The thin film 300 is coupled to the BGA substrate 20 using an adhesive (e.g., epoxy) such that at least some of the solder balls 106 are at least partially within perforations 302 of the thin film 300.

FIG. 4b shows the configuration of FIG. 4a during a solder reflow process, wherein the BGA substrate 20 is electrically coupled to the PCB 104 using the solder balls 106. Because the heatsink 102 abuts the chip 10, the solder balls 106 and corresponding solder joints 108 are subjected to mechanical stress, as described above. However, because the thin film 300 abuts the BGA substrate 20 and the PCB 104, the thin film 300 supports the BGA substrate 20 and the solder joints 108. In this way, the BGA substrate 20 and the solder joints 108 are not subjected to so much stress that solder ball short circuits form or the solder joints 108 become damaged as described above.

FIG. 4c shows a detailed view of the BGA substrate 20 coupled to the PCB 104 by way of the solder balls 106, and the thin film 300 situated therebetween. The stress applied to the BGA substrate 20 and the solder balls 106 by the heatsink 102 causes the solder balls 106 to be compressed, as described above. This compression causes the solder balls 106 to horizontally expand toward adjacent solder balls 106. However, because the thin film 300 is situated between some or all pairs of solder balls 106, the solder balls 106 do not expand to the degree that the solder balls 106 would expand in the absence of the thin film 300. Furthermore, for the same reason, the likelihood of two solder balls 106 causing a short circuit by coming into electrical contact with each other is considerably low or virtually nonexistent. Also, unlike underfill material, because the thin film 300 is not permanently fixed between the substrate 20 and the PCB 104, the thin film 300 may allow for replacement of an improperly-functioning package 100. Enabling such package replacements may substantially reduce costs compared to those incurred by using an underfill material between the substrate 20 and the PCB 104.

The thin film 300 may be fabricated using any suitable process such as that shown in FIG. 5. The liquid photo imaging process of FIG. 5 may begin with exposing a film material to light in accordance with the design of the thin film 300 (block 502). In this way, at least some portions of the film are chemically altered. The process may be further continued by processing or developing the film using etchants, such that at least some of the portions of the film are etched away, leaving a film having a pattern substantially similar to the pattern of the thin film 300 or some other desired thin film pattern (block 504). Finally, the film is cured, such as by heating the film in an oven until the film is dry (block 506). The order of the acts depicted in FIG. 5 may be altered as desired. The scope of disclosure is not limited to the specific process shown in FIG. 5. Any process that produces the thin film 300 and the perforations 302 in the thin film 300 (e.g., mechanical drill process, mechanical punching process, laser drill process) may be used. Furthermore, although the thin film 300 preferably is produced using polyimide, any suitable (e.g., nonconductive) material may be used.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system, comprising:
a ball grid array (“BGA”) substrate adapted to electrically couple to an application board using a plurality of solder balls; and
a film adapted to abut the application board and the BGA substrate, said film comprising a plurality of perforations, the solder balls adapted to couple to the application board through said perforations.

2. The system of claim 1, wherein the film is made of polyimide.

3. The system of claim 1, wherein the film is fabricated using a process selected from a group consisting of a mechanical drilling process and a mechanical punching process.

4. The system of claim 1, wherein the film is fabricated using a liquid photo imaging process.

5. The system of claim 1, further comprising an integrated circuit abutting the BGA substrate on a side of the BGA substrate opposite the solder balls.

6. The system of claim 1, wherein the film prevents a solder ball from establishing electrical contact with another solder ball.

7. The system of claim 1, wherein the film is coupled to the BGA substrate using an epoxy adhesive.

8. A method, comprising applying a perforated film to a substrate so that at least some solder balls formed on the substrate are electrically accessible to a circuit board through perforations of the perforated film, said film abutting the substrate and the circuit board.

9. The method of claim 8, further comprising forming said perforated film from polyimide.

10. The method of claim 8, further comprising forming the perforated film by:
exposing the film to light in accordance with a desired perforation pattern; and
etching away at least a portion of the film by subjecting the film to an etchant.

11. The method of claim 10, further comprising curing the film.

12. The method of claim 8, further comprising forming the perforated film using a process selected from a group consisting of a mechanical drilling process and a mechanical punching process.

13. The method of claim 8, wherein applying the perforated film to the substrate comprises using an epoxy adhesive to adhere the film to the substrate.

14. A film comprising perforations formed therein, at least some perforations adapted to each contain at least a portion of a solder ball of a ball grid array substrate such that the solder ball can be electrically coupled to a circuit board, wherein the film abuts the substrate and the circuit board.

15. The film of claim 14, wherein the film is made of polyimide.

16. The film of claim 14, wherein the film is made using a process selected from a group consisting of a mechanical drilling process, a mechanical punching process, and a laser drilling process.

17. The film of claim 14, wherein the film is of a thickness substantially similar to a solder ball diameter.

18. The film of claim 14, wherein the film is thicker than approximately 25 micrometers.
